(19) United States
(12) Patent Application Publication
(10) Pub. No.: US 2014/0345690 A1
(43) Pub. Date: Nov. 27, 2014

(54) METHOD OF MANUFACTURING SOLAR CELL MODULE AND SOLAR CELL MODULE

(71) Applicant: SANYO ELECTRIC CO., LTD., Osaka (JP)

(72) Inventors: Shigeharu TAIRA, Amagasaki (JP); Atsushi SAITA, Kobe (JP); Yukihiro YOSHIMINE, Kobe (JP)

(21) Appl. No.: 14/455,967

(22) Filed: Aug. 11, 2014

Related U.S. Application Data
(63) Continuation of application No. PCT/JP2012/055845, filed on Mar. 7, 2012.

(51) Int. Cl. H01L 31/05; H01L 31/048; H01L 31/0216; H01L 31/052

(52) U.S. Cl. CPC H01L 31/0516; H01L 31/0522; H01L 31/048; H01L 31/02165
USPC 136/259; 438/65

(57) ABSTRACT

A solar cell module includes a solar cell, a light-receiving surface member arranged on a light-receiving surface side of the solar cell, a rear surface member arranged on a rear surface side of the solar cell, a transparent filler layer arranged between the solar cell and the light-receiving surface member, and a colored filler layer arranged between the solar cell and the rear surface member. The colored filler layer exists on at least part of a portion of the light receiving surface of the solar cell, the portion located over a non-power generation region.

### CROSS REFERENCE TO RELATED APPLICATIONS

This application is a continuation application of International Application No. PCT/JP2012/055845, filed on Mar. 7, 2012, entitled “METHOD FOR MANUFACTURING SOLAR CELL MODULE, AND SOLAR CELL MODULE”, the entire contents of which are incorporated herein by reference.

### BACKGROUND

The invention relates to a method of manufacturing a solar cell module and a solar cell module.

Patent Document 1 describes a solar cell module including back junction solar cells.

Patent Document 1: Japanese Patent Application Publication No. 2009-266848

### SUMMARY OF THE INVENTION

There is a demand for further improvement of photoelectric conversion efficiency of a solar cell module including back junction solar cells.

One aspect of the invention provides a method capable of manufacturing a solar cell module with improved photoelectric conversion efficiency.

In a method of manufacturing a solar cell module according to an embodiment, a laminate is fabricated in which a light-receiving surface member, a transparent resin sheet, a solar cell, a colored resin sheet and a rear surface member are stacked in this order. Then, the laminate is pressed while being heated with a plate placed on top of the rear surface member of the laminate. The plate has a thick portion covering at least part of an area not provided with the solar cell, and a thin portion covering an area provided with the solar cell and being thinner than the thick portion.

A solar cell module according to an embodiment includes a solar cell, a light-receiving surface member, a rear surface member, a transparent filler layer, and a colored filler layer. The light-receiving surface member is arranged on a light-receiving surface side of the solar cell. The rear surface member is arranged on a rear surface side of the solar cell. The transparent filler layer is arranged between the solar cell and the light-receiving surface member. The colored filler layer is arranged between the solar cell and the rear surface member. The colored filler layer exists on at least part of a portion of the light receiving surface of the solar cell, the portion located over a non-power generation region.

The embodiments above provide a method of manufacturing a solar cell module with improved photoelectric conversion efficiency.

### BRIEF DESCRIPTION OF THE DRAWINGS

FIG. 1 is a schematic exploded cross-sectional view of a laminate fabricated in an embodiment.

FIG. 2 is a schematic plan view of the laminate and a plate fabricated in the embodiment. In FIG. 2, an area where the plate is provided is hatched, but the hatched area does not present a cross section.

FIG. 3 is a schematic cross-sectional view of the solar cell module manufactured in the embodiment.

FIG. 4 is a schematic back side view for explaining a relationship between a colored filler layer and solar cells in the solar cell module manufactured in the embodiment. In FIG. 4, an area where the colored filler layer is provided is hatched, but the hatched area does not present a cross section. In FIG. 4, a light-receiving surface member and a transparent filler layer are omitted from illustration.

FIG. 5 is a schematic plan view of a laminate and a plate fabricated in a modified example. In FIG. 5, an area where the plate is provided is hatched, but the hatched area does not present a cross section.

FIG. 6 is a schematic plan view for explaining a relationship between a colored filler layer and solar cells in a solar cell module manufactured in the modified example. In FIG. 6, an area where the colored filler layer is provided is hatched, but the hatched area does not present a cross section. In FIG. 6, a light-receiving surface member and a transparent filler layer are omitted from illustration.

FIG. 7 is a schematic exploded cross-sectional view of a laminate fabricated in another modified example.

FIG. 8 is a schematic plan view of the laminate and a plate fabricated in the other modified example. In FIG. 8, areas where thick portions of the plate are provided are hatched, but the hatched areas do not present cross sections.

### EMBODIMENTS

Hereinafter, exemplary preferred embodiments are described. It should be noted that the following embodiment is provided just for illustrative purposes. The invention is not limited at all to the following embodiment.

In the drawings referred to in the embodiment and other part, components having substantially the same function are referred to with the same reference numeral. In addition, the drawings referred to in the embodiment and other part are illustrated schematically, and the dimensional ratio and the like of objects depicted in the drawings are different from those of actual objects in some cases. The dimensional ratio and the like of objects are different among the drawings in some cases. The specific dimensional ratio and the like of objects should be determined with the following description taken into consideration.

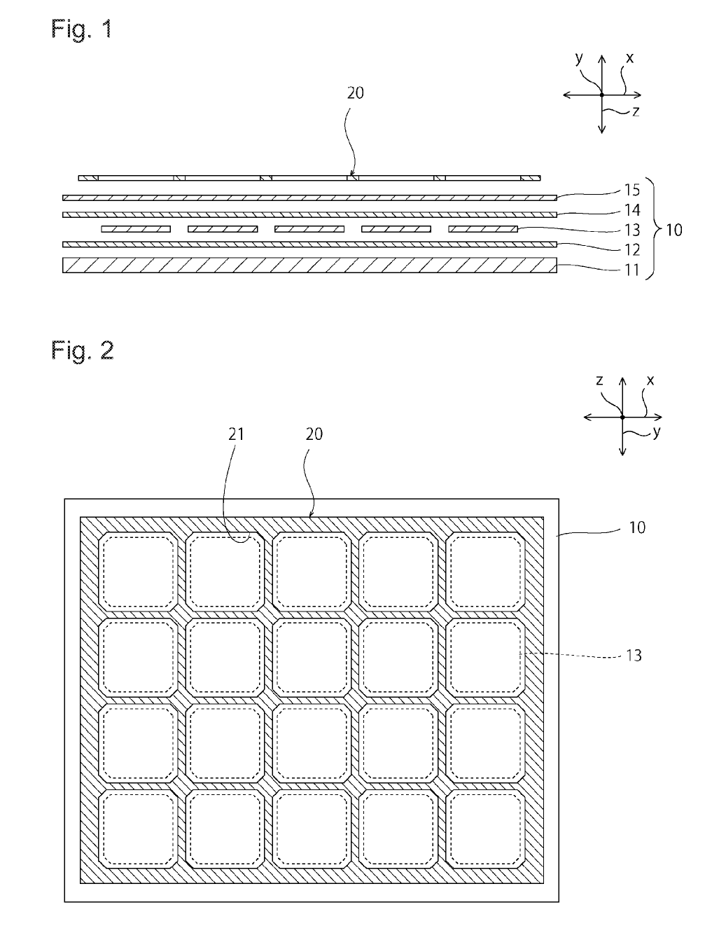

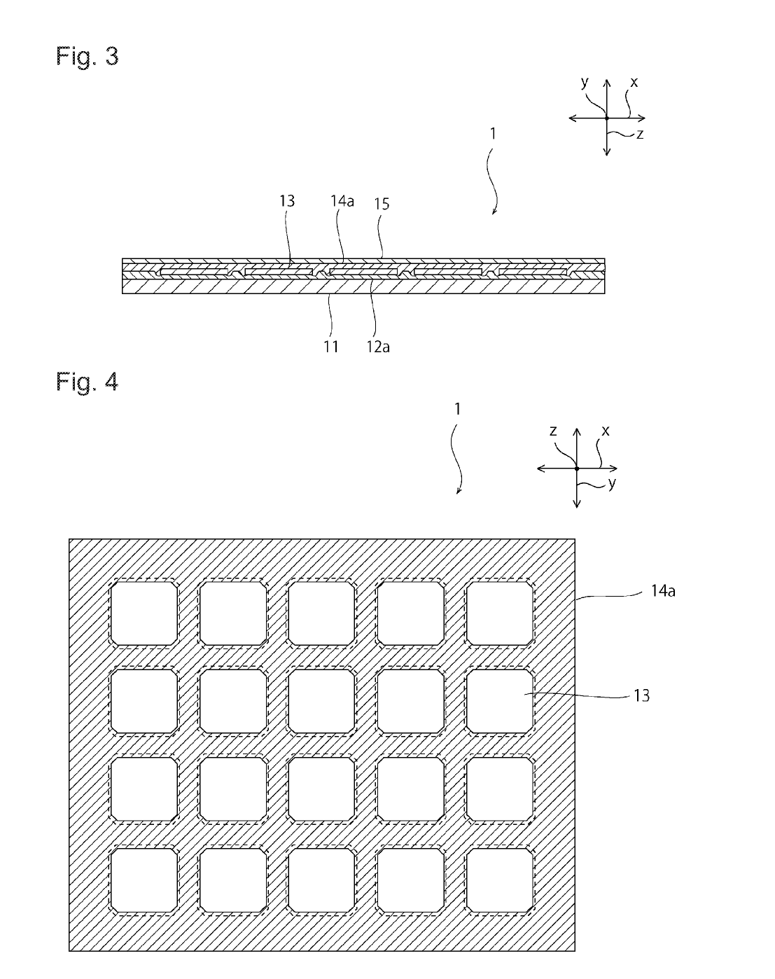

A method of manufacturing solar cell module 1 illustrated in FIGS. 3 and 4 is described mainly with reference to FIGS. 1 and 2.

First of all, laminate 10 illustrated in FIG. 1 is fabricated. Specifically, laminate 10 is fabricated by stacking light-receiving surface member 11, translucent or transparent resin sheet 12, solar cells 13, colored resin sheet 14 and rear surface member 15 in this order. Instead, laminate 10 may be fabricated by stacking rear surface member 15, colored resin sheet 14, solar cells 13, transparent resin sheet 12 and light-receiving surface member 11 in this order. In other words, the stacking order to fabricate laminate 10 is not particularly limited.

Light-receiving surface member 11 may be made of, for example, a glass plate, a ceramic plate, or a resin plate. Transparent resin sheet 12 may be made of a resin sheet substantially containing no pigment or dye. Transparent resin sheet 12 may be made of, for example, a crosslinkable resin such as an ethylene-vinyl acetate copolymer (EVA) or a non-crosslinkable resin such as polyolefin.

Solar cells 13 may be formed of, for example, crystalline silicon solar cells, thin film solar cell, or the like. In this embodiment, a plurality of solar cells 13 are arranged at intervals. Specifically, solar cells 13 are arranged in a matrix pattern. Solar cells 13 are electrically connected to each other via wiring members not illustrated. Instead, only one solar cell 13 may be arranged.

Solar cell 13 may have, for example, a rectangular shape, a polygonal shape, or a rectangular shape with corners chamfered or rounded.

Colored resin sheet 14 may be made of a resin sheet containing at least one of a pigment and a dye. The color of colored resin sheet 14 is not particularly limited, but the preferable color is white, for example. For example, colored resin sheet 14 is preferably formed of a resin sheet made of a crosslinkable resin such as an ethylene-vinyl acetate copolymer (EVA) or a non-crosslinkable resin sheet such as polyolefin, the resins containing titanium dioxide particles. Rear surface member 15 may be made of, for example, a resin sheet, a resin sheet containing a metal layer, or the like.

Next, plate 20 is placed on top of laminate 10. As illustrated in FIG. 2, plate 20 is placed to cover at least part of an area not provided with solar cells 13. Plate 20 has openings 21 existing over areas provided with solar cells 13. Thus, plate 20 does not cover the areas provided with solar cells 13. More specifically, plate 20 is arranged to cover at least part of the area between adjacent solar cells 13 and the area outside outermost solar cells 13. Plate 20 is arranged to surround the periphery of each of solar cells 13. Plate 20 is provided in a lattice form.

A constituent material for plate 20 is not particularly limited. Plate 20 may be preferably made of, for example, a composite material of a metal, resin, ceramic and the like.

Subsequently, laminate 10 on which plate 20 is placed is pressed while being heated. In this way, solar cell module 1 illustrated in FIGS. 3 and 4 can be completed.

Solar cell module 1 includes a plurality of solar cells 13. Solar cells 13 are arranged at intervals in the matrix pattern. Solar cells 13 are electrically connected to each other via the wiring members not illustrated. Light-receiving surface member 11 is arranged on a light-receiving surface side of solar cells 13. On the other hand, rear surface member 15 is arranged on a rear surface side of solar cells 13. Transparent filler layer 12a is arranged between solar cells 13 and light-receiving surface member 11. Transparent filler layer 12a is made of transparent resin sheet 12. Colored filler layer 14a is arranged between solar cells 13 and rear surface member 15. Colored filler layer 14a is made of colored resin sheet 14.

As described above, laminate 10 is pressed while being heated in a state where plate 20 covering at least part of the area not provided with solar cells 13 is placed on rear surface member 15. As a result, as illustrated in FIG. 3, softened colored resin sheet 14 comes around on the light-receiving surface side of solar cells 13. Thus, colored filler layer 14a exists on at least part of a portion of the light receiving surface of each solar cell 13, the portion located over a non-power generation region. This inhibits light from entering the non-power generation regions of the light receiving surfaces of solar cells 13. Thereby, at least part of light that would otherwise enter the non-power generation regions of the light receiving surfaces of solar cells 13 can be guided to power generation regions of solar cells 13. As a result, improved photoelectric conversion efficiency can be achieved.

In order to obtain further improved photoelectric conversion efficiency, it is preferable to press laminate 10 so that colored resin sheet 14 can come around on the portions, located over the non-power generation regions, of the light receiving surfaces of solar cells 13 while not extending into portions, located over the power generation regions, of the light receiving surfaces.

In order to obtain further improved photoelectric conversion efficiency, it is more preferable to arrange plate 20 such that plate 20 can cover at least part of the area between adjacent solar cells 13. With this arrangement, colored resin sheet 14 exists on at least part of the portion of the light receiving surface of each solar cell 13, the portion located over the non-power generation region and proximate to other solar cells 13. Thus, at least part of light that would otherwise enter the non-power generation regions of the light receiving surfaces of solar cells 13 can be guided to the power generation regions of solar cells 13 more efficiently.

In order to obtain still-further improved photoelectric conversion efficiency, it is more preferable to arrange plate 20 such that plate 20 can surround the peripheries of solar cells 13. With this arrangement, colored filler layer 14a is provided to surround the power generation regions of the light receiving surfaces of solar cells 13, so that the non-power generation regions provided outside the power generation regions can be covered with colored filler layer 14a at a high coverage. As a result, at least part of light that would otherwise enter the non-power generation regions of the light receiving surfaces of solar cells 13 can be guided to the power generation regions of solar cells 13 even more efficiently.

In the embodiment, a “power generation region” means a region that emits light when a voltage is applied to a solar cell. A “non-power generation region” means a region that does not emit light when a voltage is applied to a solar cell. In general, the light emission region is formed of a region provided with an electrode containing a transparent conductive oxide layer. The non-light emission region is formed of a region not provided with any electrode containing a transparent conductive oxide layer.

Hereinafter, a modified example of the foregoing embodiment is described. In the following description, components having functions substantially common to the foregoing embodiment is referred to with the common reference numerals, and the description thereof is omitted.

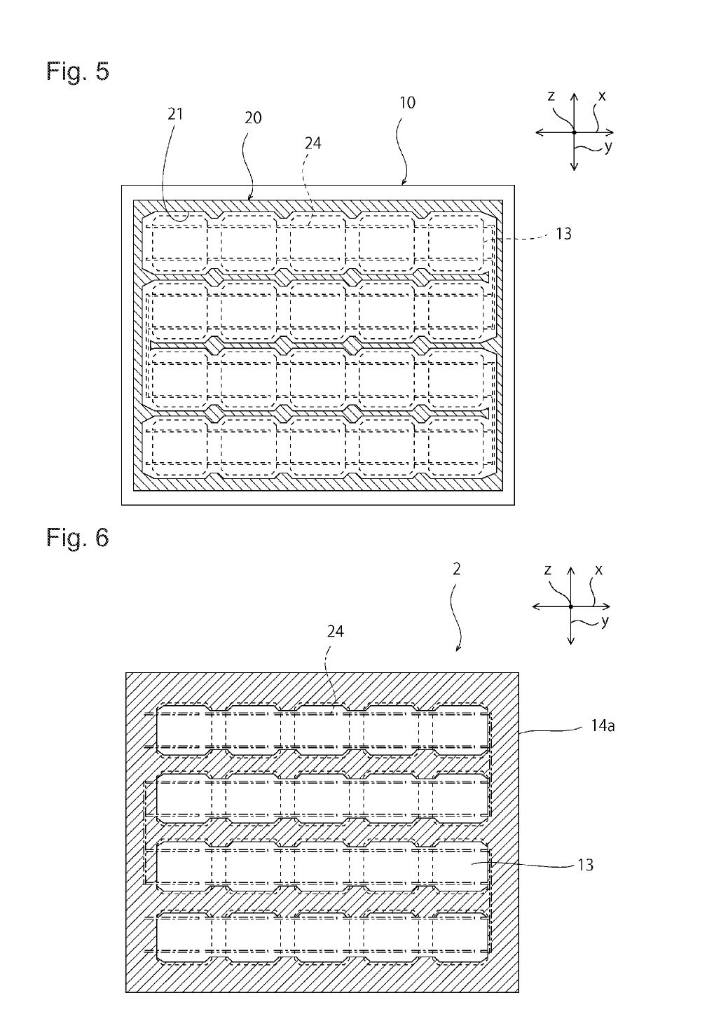

As illustrated in FIG. 5, in this modified example, plate 20 is arranged to cover some of areas between adjacent solar cells 13, that is, plate 20 does not exist on areas where wiring members 24 are provided, but plate 20 exists on the other areas where no wiring members 24 are provided. With this arrangement, as illustrated in FIG. 6, among the non-power generation regions of solar cells 13 in solar cell module 2 thus manufactured, colored filler layer 14a does not substantially exist on the non-power generation regions located along the sides of solar cells 13 across which wiring members 24 extend, while colored filler layer 14a extends over at least part of the non-power generation regions located along the sides of solar cells 13 across which no wiring members 24 extend. In this structure, improved photoelectric conversion efficiency can be obtained as well. Moreover, since there may be no risk that wiring members 24 are damaged due to flowing of colored resin sheet 14, solar cell module 2 with improved reliability can be obtained.

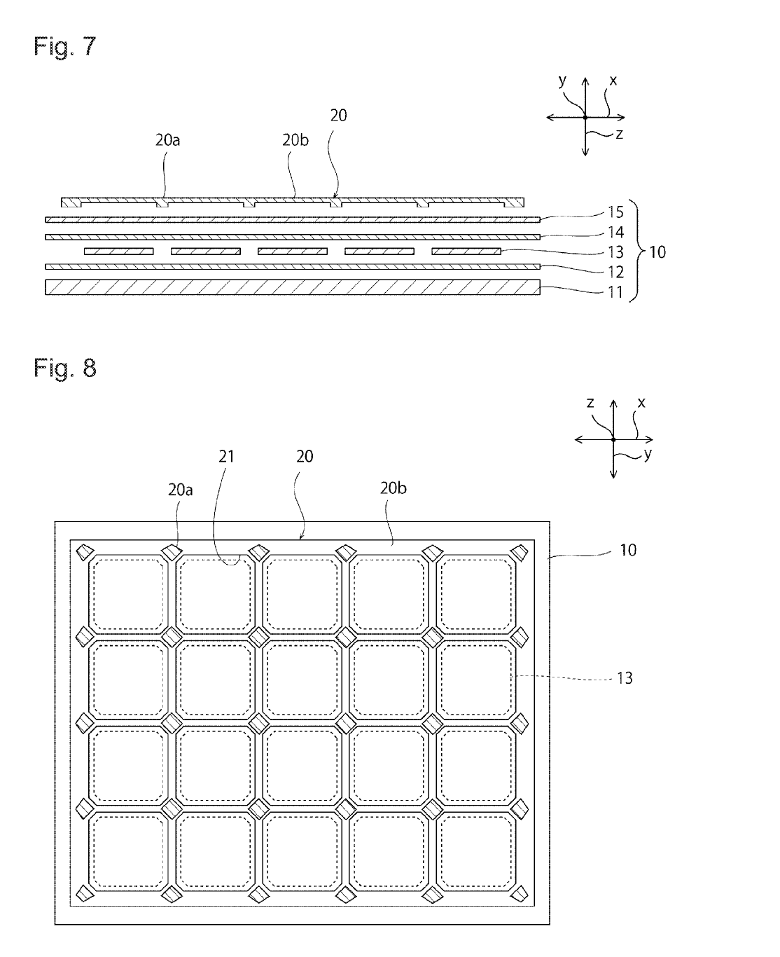

In the foregoing embodiment, the example where openings 21 are provided to plate 20 is explained. However, the invention is not limited to this. Instead of providing openings 21 to plate 20, specifically for example, thick portions 20a and a thin portion 20b may be provided to plate 20, as illustrated in FIG. 7. Thick portions 20a cover at least part of the area not provided with solar cells 13 and thin portion 20b covers areas provided with solar cells 13 and is thinner than thick portions 20a. Even in this case, colored filler layer 14a can be provided on at least part of a portion, located over the non-power generation region, of the light receiving surface of each solar cell 13. Here, plate 20 illustrated in FIG. 7 may be constructed by laminating a plate with openings and a plate with no openings together.

As illustrated in FIG. 8, thick portions 20a may be each provided at an area surrounded by corners of four solar cells 13, and thin portion 20b may be provided in the area other than the above areas.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A method of manufacturing a solar cell module comprising:
fabricating a laminate in which a light-receiving surface member, a transparent resin sheet, a solar cell, a colored resin sheet and a rear surface member are stacked in this order; and
heating and simultaneously pressing the laminate with a plate placed on the rear surface member of the laminate, the plate including a thick portion that covers at least part of an area not provided with the solar cell, and a thin portion that covers an area provided with the solar cell and is thinner than the thick portion.

2. The method of manufacturing a solar cell module according to claim 1, wherein
a plurality of the solar cells are provided between the transparent resin sheet and the colored resin sheet, and are arranged at intervals, and
the plate covers at least part of an area between adjacent ones of the solar cells.

3. The method of manufacturing a solar cell module according to claim 2, wherein
the plate surrounds peripheries of the solar cells.

4. The method of manufacturing a solar cell module according to claim 1, wherein
the thin portion has an opening.

5. The method of manufacturing a solar cell module according to claim 2, wherein
the thin portion has an opening.

6. The method of manufacturing a solar cell module according to claim 3, wherein
the thin portion has an opening.

7. The method of manufacturing a solar cell module according to claim 1, wherein
when the laminate is pressed, the colored resin sheet comes around on a surface of the non-power generation region of the solar cell at a side of the transparent resin sheet.

8. The method of manufacturing a solar cell module according to claim 2, wherein
when the laminate is pressed, the colored resin sheet comes around on a surface of the non-power generation region of the solar cell at a side of the transparent resin sheet.

9. The method of manufacturing a solar cell module according to claim 3, wherein
when the laminate is pressed, the colored resin sheet comes around on a surface of the non-power generation region of the solar cell at a side of the transparent resin sheet.

10. The method of manufacturing a solar cell module according to claim 4, wherein
when the laminate is pressed, the colored resin sheet comes around on a surface of the non-power generation region of the solar cell at a side of the transparent resin sheet.

11. A solar cell module comprising:
a solar cell;
a light-receiving surface member provided on a light-receiving surface side of the solar cell;
a rear surface member provided on a rear surface side of the solar cell;
a transparent filler layer provided between the solar cell and the light-receiving surface member; and
a colored filler layer provided between the solar cell and the rear surface member, wherein
the colored filler layer is positioned on at least a portion of a light receiving surface of the solar cell, the portion located over a non-power generation region.

12. The solar cell module according to claim 11, wherein
a plurality of the solar cells are arranged at intervals, and
the colored filler layer is positioned on at least part of a portion of a light receiving surface of the solar cell, the portion located over a non-power generation region and proximate to another solar cell.

13. The solar cell module according to claim 12, wherein
the colored filler layer surrounds the power generation regions of the light receiving surfaces of the solar cells.

14. The solar cell module according to claim 11, wherein
the colored filler layer is not positioned on a portion located over a power generation region.

15. The solar cell module according to claim 11, wherein
the colored filler layer does not cover at least an area where wiring member is provided.
